(19) United States
(12) Patent Application Publication
(10) Pub. No.: US 2025/0038053 A1
(43) Pub. Date: Jan. 30, 2025

(54) GROWTH CHAMBER SMART SEASONING

(71) Applicant: Applied Materials, Inc., Santa Clara, CA (US)

(72) Inventors: Zhepeng Cong, San Jose, CA (US); Tao Sheng, Fremont, CA (US); Ala Moradian, San Jose, CA (US)

(73) Assignee: Applied Materials, Inc., Santa Clara, CA (US)

(21) Appl. No.: 18/361,326

(22) Filed: Jul. 28, 2023

(51) Int. Cl. H01L 21/66; C23C 16/52; C30B 25/16; G05B 13/02

(52) U.S. Cl. CPC H01L 22/26; C23C 16/52; C30B 25/16; G05B 13/0265

(57) ABSTRACT

A method of analyzing completion of seasoning of semiconductor processing chambers may include training a model using seasoning cycle characteristics data obtained from existing semiconductor processing chambers. A supervised learning process may label the characteristics data based on expert determined identify seasoning completion and may optionally label the characteristics data based on chamber open event information or preventive maintenance information. The trained model may be used to characterize another chamber during seasoning to determine whether seasoning is completed and/or when or how long or how many seasoning cycles may be performed until seasoning is complete.

### TECHNICAL FIELD

This disclosure generally describes techniques for completing seasoning of a semiconductor processing chamber post preventive maintenance (PM) in a reduced amount of time as compared to conventional techniques for seasoning using a fixed time. More specifically, this disclosure describes systems and methods for smart seasoning of a semiconductor processing chamber post PM by monitoring chamber characteristics during seasoning cycles to determine when seasoning is complete so that the chamber can be qualified for wafer monitoring and fabrication.

### BACKGROUND

Epitaxial deposition may include any type of crystal growth or deposition performing new crystalline layers in a known orientation with respect to a seed layer. Many modern semiconductor devices utilize epitaxial growth on silicon substrate wafers. For example, providing a silicon-based precursor to a deposition chamber at temperatures ranging from 300 to 1200° C. may allow incremental layers of a film last to form that aligns with the crystalline lattice of the underlying seed layer. Conventional epitaxial film deposition typically includes a baking operation that may occur at greater than or about 700° C. or more. Epitaxial growth is being extended to different device structures, and may be used for selective deposition or growth on specific surfaces.

### SUMMARY

Epitaxial film process productivity is becoming more important and challenging to achieve, due to reduced temperature range and newer structures being produced as processing technology evolves, making improvements to the post preventive maintenance recover time more valuable.

In a first aspect, methods are disclosed for seasoning a semiconductor processing chamber, such as following an open chamber event or a preventive maintenance event. For example, methods of this aspect may comprise executing a seasoning cycle, monitoring characteristics of the semiconductor processing chamber, and, based on the chamber signals and historical data in a library, using a trained model to determine the completion of seasoning of the semiconductor processing chamber. In some examples, a method of this aspect comprises executing a seasoning cycle using a semiconductor processing chamber or causing the semiconductor processing chamber to execute a seasoning cycle, determining characteristics of the semiconductor processing chamber during the seasoning cycle, determining that seasoning of the semiconductor processing chamber is not complete based on the characteristics, causing the semiconductor processing chamber to execute an additional seasoning cycle, determining additional characteristics of the semiconductor processing chamber during the additional seasoning cycle, determining that seasoning of the semiconductor processing chamber is complete based on the additional characteristics, and generating an indicator identifying completion of seasoning of the semiconductor processing chamber. In some examples, a model, such as a trained machine-learning model may be used to evaluate the characteristics to determine if the seasoning is complete. For example, methods of this aspect may comprise or further comprise providing characteristics to a trained machine-learning model that is configured to receive characteristics of semiconductor processing chambers as an input and provide outputs relating to completion of seasoning of the semiconductor processing chambers. The output may be received from the trained machine-learning model and may indicate or be used to determine whether seasoning of the semiconductor processing chamber is complete or not complete. The process of repeating executing seasoning cycles, measuring or monitoring characteristics of the semiconductor processing chamber during the seasoning cycles, providing the characteristics to the model, and based on the model output determining if the seasoning is complete may be repeated one or more times as needed until seasoning is determined to be complete.

In some non-limiting examples, output from the model may indicate completion of seasoning of the semiconductor processing chamber, an expected time of completion of seasoning of the semiconductor processing chamber, an expected duration of seasoning of the semiconductor processing chamber, an expected number of additional seasoning cycles for completion of seasoning of the semiconductor processing chamber, or any combination of these. In some non-limiting examples, methods of this aspect may generate a separate indicator identifying one or more of the expected time of completion of seasoning of the semiconductor processing chamber, the expected duration of seasoning of the semiconductor processing chamber, the expected number of additional seasoning cycles for completion of seasoning of the semiconductor processing chamber, or any combination of these. Such indicators may be generated subsequent to determining that seasoning of the semiconductor processing chamber is not complete and can be useful for communicating information to a user about the seasoning process.

In some examples, a seasoning cycle may comprise one or both controlling a semiconductor processing chamber to establish an etch condition within the semiconductor processing chamber or controlling the semiconductor processing chamber to establish an epitaxial growth condition within the semiconductor processing chamber, in either order. In any examples, execution of a seasoning cycle may comprise one or more of controlling the semiconductor processing chamber to establish an etch condition within the semiconductor processing chamber or controlling the semiconductor processing chamber to establish an epitaxial growth condition within the semiconductor processing chamber. In some examples, the semiconductor processing chamber may be controlled to both establish an etch condition and an epitaxial growth condition, in either order, for a seasoning cycle.

In any examples, characteristics of the semiconductor processing chamber may be monitored, measured, or otherwise determined during execution of a seasoning cycle and/or used by a machine-learning model in evaluating completion of a seasoning process. In some non-limiting examples, the characteristics may comprise one or more of a temperature within the semiconductor processing chamber during the seasoning cycle, a thickness of an epitaxial layer generated within the semiconductor processing chamber, a power delivered to a heater associated with the semiconductor processing chamber, a power setting for a heater associated with the semiconductor processing chamber, a growth rate within the semiconductor processing chamber during the seasoning cycle, an etch rate within the semiconductor processing chamber during the seasoning cycle, an optical condition within the semiconductor processing chamber during the seasoning cycle, a pressure within the semiconductor processing chamber during the seasoning cycle, a gas composition within the semiconductor processing chamber during the seasoning cycle, a flow rate into or out of the semiconductor processing chamber during the seasoning cycle, a change in any of these, or any combination of these, or optionally various physical or structural parameters associated with the semiconductor processing chamber, such as geometrical details of the semiconductor processing chamber or any component thereof or therein, design specifications for the semiconductor processing chamber or any component thereof or therein. In some non-limiting examples, characteristics may comprise, correspond to, or be derived from sensor data from one or more optical sensors, heat sources, thermal sensors, piezo sensors, or the like. Optionally, characteristics may comprise or correspond to virtual sensor data derived from one or more of a temperature within the semiconductor processing chamber during the seasoning cycle, a thickness of an epitaxial layer generated within the semiconductor processing chamber, a power delivered to a heater associated with the semiconductor processing chamber, a power setting for a heater associated with the semiconductor processing chamber, a growth rate within the semiconductor processing chamber during the seasoning cycle, an etch rate within the semiconductor processing chamber during the seasoning cycle, an optical condition within the semiconductor processing chamber during the seasoning cycle, a pressure within the semiconductor processing chamber during the seasoning cycle, a gas composition within the semiconductor processing chamber during the seasoning cycle, a flow rate into or out of the semiconductor processing chamber during the seasoning cycle, a change in any of these, or any combination of these, or optionally various physical or structural parameters associated with the semiconductor processing chamber, such as geometrical details of the semiconductor processing chamber or any component thereof or therein, design specifications for the semiconductor processing chamber or any component thereof or therein.

Methods of this aspect may comprise or further comprise training the machine-learning model. For example, the machine-learning model may be trained prior to providing the characteristics for generating the output. In examples, training the machine-learning model comprises receiving training characteristics from a plurality of executions of seasoning cycles executed by one or more semiconductor processing chambers, such as one or more reference semiconductor processing chambers, an generating training data based on the training characteristics. In some examples, methods of this aspect comprise receiving input corresponding to labeling information for the plurality of executions of seasoning cycles. In examples, the training data is generated using labeling information identifying completion of seasoning of the one or more semiconductor processing chambers. Example labeling information may comprise or correspond to information indicating a seasoning cycle at which seasoning is determined to be complete, such as may be determined according to expert or user analysis. Example labeling information may comprise or correspond to information about an open chamber event or a preventive maintenance event associated with the plurality of seasoning cycles, such as information indicating chamber open duration, information indicating changes of components within the semiconductor processing chamber, information indicating preventive maintenance procedures or protocols used (e.g., dry air purge, exposure to ambient air, exposure to water), or the like. Once the training data is prepared, methods of this aspect may further comprise executing a supervised learning algorithm to train the machine-learning model using the training data. In this way, the machine-learning model may be specially adapted to generate output information based on input characteristics information to provide meaningful analysis of completion of a seasoning process.

In some examples, the training characteristics may be derived from or obtained using the same semiconductor processing chamber that is undergoing seasoning, such as with a different processing kit and/or equipment in the same semiconductor processing chamber. For example, the training characteristics may correspond to characteristics obtained during previous seasoning processes for the semiconductor processing chamber.

Optionally, the training of the machine-learning model may be continuously updated with each seasoning process that is completed. In some examples, methods of this aspect may comprise executing one or more additional seasoning cycles using the semiconductor processing chamber or causing the semiconductor processing chamber to execute one or more additional seasoning cycles after determining that seasoning of the semiconductor processing chamber is complete, such as for purposes of obtaining additional characteristics information for the semiconductor processing chamber where seasoning is complete for use in confirming completion and/or updating the training of the machine-learning model. In such a circumstance, determining that seasoning of the semiconductor processing chamber is complete may comprises comparing characteristics of the semiconductor processing chamber with previously determined characteristics of the semiconductor processing chamber, such as characteristics of the semiconductor processing chamber obtained when the semiconductor processing chamber was in a seasoned state.

Optionally, a user may override the completion determined by the trained machine learning model and manually trigger executing one or more additional seasoning cycles using the semiconductor processing chamber or causing the semiconductor processing chamber to execute one or more additional seasoning cycles after determining that seasoning of the semiconductor processing chamber is complete. This may be useful, in some cases, for confirming seasoning completion prior to using the semiconductor processing chamber in a production environment where processing of a semiconductor device is to take place. In some cases, methods of this aspect may comprise receiving input indicating that an open chamber event or preventive maintenance event is to take place and, in response, executing one or more additional seasoning cycles or causing the semiconductor processing chamber to execute one or more additional seasoning cycles and determining characteristics of the semiconductor processing chamber during the one or more additional seasoning cycle. In this way, historical characteristics data may be obtained prior to the open chamber event or preventive maintenance event that can be used in determining whether seasoning is complete following the open chamber event or preventive maintenance event.

In any methods of this aspect, the machine learning model may perform a regression analysis and/or a classification analysis, such as using various characteristics determined during one or more seasoning cycles. For example, a regression analysis may analyze measured characteristics information or virtual sensor data, for example, to predict seasoning behavior, which may be informed by training data and/or labeling information. Similarly, a classification analysis may analyze characteristics determined during one or more seasoning cycles, optionally taken together with labeling information such as identifying open chamber even or preventive maintenance event information to classify the seasoning process for meaningful comparison with appropriate training data. Whether using a regression analysis or a classification analysis, or both or other analysis techniques, the machine learning model can be used to identify or map true positives in previous characteristics data associated with known seasoning processes in a training data set to establish a high confidence in the machine learning model to predict seasoning completion. In any methods of this aspect, the machine learning model may compare characteristics for a seasoning cycle with corresponding characteristics for an immediately previous seasoning cycle to evaluate completion of seasoning of the semiconductor processing chamber. Some examples include where the machine learning model determines a change in characteristics between the current cycle and the immediately previous seasoning cycle and evaluates completion of seasoning of the semiconductor processing chamber base on whether the change in characteristics is below a threshold value. In some cases, the threshold value may be determined in advance by the trained machine-learning model. Optionally, the threshold value may be adjusted, such as by receiving input corresponding to a user determined threshold value or threshold value override.

In another aspect, systems are provided herein, such as semiconductor processing chambers and systems for operating semiconductor processing chambers. For example, systems of this aspect may be configured or adapted to season a semiconductor processing chamber and automatically determine when seasoning of the semiconductor processing chamber is completed, such as based on sensor data or other characteristics measured or monitored during the seasoning process. In some examples, systems of this aspect may be configured to, adapted to, or programmed to perform any of the methods described herein. In some examples, a system of this aspect may comprise one or more processors and one or more non-transitory computer readable storage devices comprising instructions that, when executed by the one or more processors, cause the one or more processors to perform operations. In some examples, the operations may comprise causing the semiconductor processing chamber to execute a seasoning cycle, determining characteristics of the semiconductor processing chamber during the seasoning cycle, providing the characteristics to a trained machine-learning model that is configured to receive characteristics of semiconductor processing chambers as an input and provide outputs relating to completion of seasoning of the semiconductor processing chambers, receiving the output from the trained machine-learning model, determining that seasoning of the semiconductor processing chamber is not complete based on the output, causing the semiconductor processing chamber to execute an additional seasoning cycle, continuing determining characteristics of the semiconductor processing chamber during the additional seasoning cycle, providing the characteristics of the semiconductor processing chamber during the additional seasoning cycle to the trained machine-learning model, receiving additional output from the trained machine-learning model, determining that seasoning of the semiconductor processing chamber is complete based on the additional output; and generating an indicator identifying completion of seasoning of the semiconductor processing chamber. In some examples, a system of this aspect may comprise further comprise one or more sensors in data communication with the one or more processors for determining characteristics of the semiconductor processing chamber during seasoning cycles. Nonlimiting examples of sensors include optical sensors, heat sources, thermal sensors, piezo sensors, or the like. It will be appreciated that a heat source may be useful as a sensor in that the power consumption or power output of the heat source can be measured by or during operation of the heat source.

In the systems and methods described herein, characteristics may optionally comprise or correspond to a time series of data obtained from one or more sensors. Optionally, characteristics may comprise or correspond to a comparison using a first time series of data obtained from the one or more sensors during a first seasoning cycle and a second time series of data obtained from the one or more sensors during a second seasoning cycle immediately previous to the first seasoning cycle.

In any examples, a semiconductor processing chamber may comprise one or more of a quartz dome, a flow module, or a susceptor. Optionally, a semiconductor processing chamber may comprise any other suitable components, such as one or more sensors, flow modules, heat sources, light sources, windows, or the like. In some examples, systems described herein may comprise or further comprise one or more sensors positioned to measure characteristics of a surface of one or more of the quartz dome, the flow module, the susceptor, or a substrate within the semiconductor processing chamber.

In an other aspect, computer program products are described herein. An example computer program product may comprise, for example, a non-transitory computer-readable medium comprising instructions that, when executed by one or more processors, cause the one or more processors to perform operations. Without limitation, the operations may correspond to any of the methods described herein. For example the operations may comprise causing a semiconductor processing chamber to execute a seasoning cycle, determining characteristics of the semiconductor processing chamber during the seasoning cycle, providing the characteristics to a trained machine-learning model that is configured to receive characteristics of semiconductor processing chambers as an input and provide outputs relating to completion of seasoning of the semiconductor processing chambers, receiving the output from the trained machine-learning model, determining that seasoning of the semiconductor processing chamber is not complete based on the output, causing the semiconductor processing chamber to execute an additional seasoning cycle, continuing determining characteristics of the semiconductor processing chamber during the additional seasoning cycle, providing the characteristics of the semiconductor processing chamber during the additional seasoning cycle to the trained machine-learning model, receiving additional output from the trained machine-learning model, determining that seasoning of the semiconductor processing chamber is complete based on the additional output, and generating an indicator identifying completion of seasoning of the semiconductor processing chamber.

As discussed elsewherein herein, the trained machine-learning model may be trained to model seasoning of the semiconductor processing chamber following a chamber open event or a preventive maintenance event associated with the semiconductor processing chamber. Optionally, methods, systems, or computer program products described herein may comprise or be configured to perform operations including obtaining user inputs corresponding to one or more of identification of a duration of the chamber open event or the preventive maintenance event, a change in components of the semiconductor processing chamber during the chamber open event or the preventive maintenance event, environmental conditions during the chamber open event or the preventive maintenance event, maintenance procedures or protocols applied to the semiconductor processing chamber during the chamber open event or the preventive maintenance event, or a severity rating for the chamber open event or the preventive maintenance event. In examples, the trained machine-learning model may be further configured to use the user inputs when generating the outputs relating to completion of seasoning of the semiconductor processing chambers. Non-limiting examples include information about chamber open duration, information about changes of components within the semiconductor processing chamber, information about preventive maintenance procedures or protocols used (e.g., dry air purge, exposure to ambient air, exposure to water). This information may be beneficially used in or by the trained machine-learning model to evaluate the progress of a seasoning process and provide insights into the rate at which seasoning progresses, since the seasoning process may correspond to a physical process where surface components are passivated, such as by removal or desorption of water, during cyclic exposure to etch conditions and growth conditions, and various information about the open chamber event or preventive maintenance event may indicate a longer seasoning process may likely occur due to larger amounts of water being possibly incorporated into the semiconductor processing chamber during the chamber open event or routine maintenance event.

Optionally, output from the trained machine-learning model may comprise or correspond to an indication of completion or non-completion of seasoning of the semiconductor processing chamber and/or one or more variance values for one or more characteristics or environmental variables. The one or more variance values may be determined, for example, by comparing the characteristics of the semiconductor processing chamber during a first seasoning cycle with characteristics of the semiconductor processing chamber during a second seasoning cycle immediately previous to the first seasoning cycle. In some examples, determining that seasoning of the semiconductor processing chamber is complete based on output from the trained machine-learning model may comprise deriving a variance value between the output for a first seasoning cycle and output for second seasoning cycle immediately previous to the first seasoning cycle, and determining that the variance value is less that a target variance value. In some examples, input corresponding to a tolerance to the model may be received that indicates an allowed deviation from the target variance value, which may correspond to a user override, allowing user control to reduce or increase the number of seasoning cycles on the fly.

Without wishing to be bound by any particular theory, there can be discussion herein of beliefs or understandings of underlying principles relating to the invention and operations or parameters described herein. It is recognized that regardless of the ultimate correctness of any mechanistic explanation or hypothesis, the example and embodiments described can nonetheless be operative and useful.

### BRIEF DESCRIPTION OF THE DRAWINGS

A further understanding of the nature and advantages of various embodiments and examples may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a schematic side cross-sectional view of a semiconductor processing chamber, according to some embodiments.

FIG. 2 illustrates a flowchart of a method for training a machine-learning model to characterize completion of seasoning of a semiconductor processing chamber, according to some embodiments.

FIG. 3 illustrates a block diagram of how semiconductor processing chamber sensor characteristics data may be collected and processed to generate virtual sensor data, according to some embodiments.

FIG. 4 illustrates graphs of time series data measured during seasoning cycles by a semiconductor processing chamber, according to some embodiments.

FIG. 5 illustrates a bar graph displaying virtual sensor data used by a machine-learning model during seasoning of a semiconductor processing chamber, according to some embodiments.

FIG. 6A, FIG. 6B, FIG. 6C, and FIG. 6D illustrates additional bar graphs displaying virtual sensor data used by a machine-learning model during seasoning of semiconductor processing chambers subjected to different open event or preventive maintenance event conditions, according to some embodiments.

FIG. 7 illustrates a flow diagram for training a model to predict semiconductor processing chamber seasoning completion, according to some embodiments.

FIG. 8 illustrates a flowchart of a method for seasoning semiconductor processing chambers, according to some embodiments.

FIG. 9 illustrates a flow diagram of using a trained machine-learning model to evaluation completion of seasoning of a semiconductor processing chamber, according to some embodiments.

FIG. 10 illustrates an exemplary computer system, in which various embodiments may be implemented.

### DETAILED DESCRIPTION

Thermal Chemical Vapor Deposition (CVD) is one of the highest-temperature processes in semiconductor manufacturing. During the deposition process, precursor gases may flow into a semiconductor processing chamber at temperatures ranging between about 300° C. and about 1200° C. during deposition, etching, and/or chamber cleaning processes. Temperature setpoints may change throughout the process according to the processing recipe, and the temperature within the semiconductor processing chamber can ramp up/down between different setpoints based on the thermal characteristics of the chamber and as different gasses are flowed into or out of the chamber. The rate and quality of the epitaxial growth or etch may be dependent not only on the absolute temperature and gas mixture, but also the consistent behavior of the semiconductor processing chamber. Broadly, the epitaxial growth and/or etch performance within a semiconductor processing chamber may vary based on the processing history of the chamber. For best performance, a semiconductor processing chamber should exhibit very stable conditions between different epitaxial growth cycles or etch cycles.

At a more detailed level, the epitaxial growth and etch behavior within a semiconductor processing chamber may change due to the presence of water or impurities (e.g., halide salts) within or on surface of the chamber or components therein. Semiconductor processing chambers may be opened or subjected to preventive maintenance on a regular basis within a production or research facility, allowing the introduction of contaminants or other changes in surfaces. For example, exposure to the atmosphere can introduce water into a semiconductor processing chamber, and changing processing equipment during preventive maintenance or troubleshooting can introduce water or other impurities, or alter the balance or presence of passivated surfaces. Different open chamber events or preventive maintenance events can expose the semiconductor processing chamber to different environmental conditions (e.g., relative humidity) for various durations, or change various different components, and destabilize conditions.

To restore performance following an open chamber or preventive maintenance event, semiconductor processing chambers can be subjected to a cycling process, generally referred to herein as “seasoning,” where the temperature and gas mixture within the chamber are repeatedly cycled, such as between etch conditions and epitaxial growth conditions. Seasoning can be useful for driving out moisture and/or impurities introduced to or absorbed within or on the semiconductor processing chamber, establishing a passivated surfaces of the semiconductor processing chamber or components therein, or otherwise bringing a semiconductor processing chamber back to pre-open chamber event or pre-preventive maintenance event conditions. Since it can take varying amounts of seasoning cycles to return to pre-open chamber event or pre-preventive maintenance event conditions based on the duration of the event, the environmental conditions during the event, changes in internal components during the event, or the like, a typical protocol for seasoning is to subject a semiconductor processing chamber to a large, fixed number of seasoning cycles, which can be sufficient for establishing stable conditions following any open chamber event or preventive maintenance event.

In many cases, however, the large, fixed number of seasoning cycles in conventional seasoning processes can be excessive for establishing stable conditions, as some semiconductor processing chambers can be seasoned after some open chamber events or preventive maintenance events using fewer seasoning cycles. Since each seasoning cycle takes time, subjecting a semiconductor processing chamber to excessive seasoning cycles can reduce available production time. The present disclosure overcomes this and other issues by establishing a technique for monitoring conditions within the semiconductor processing chamber to determine when sufficient seasoning is achieved, and/or the semiconductor processing chamber is returned to or has established conditions suitably stable for production. Moreover, aspects described herein include using a trained machine-learning model to evaluate monitored conditions to automatically determine when seasoning is complete or to provide feedback to a user about the expected duration or number of seasoning cycles required to return the semiconductor processing chamber to stable conditions.

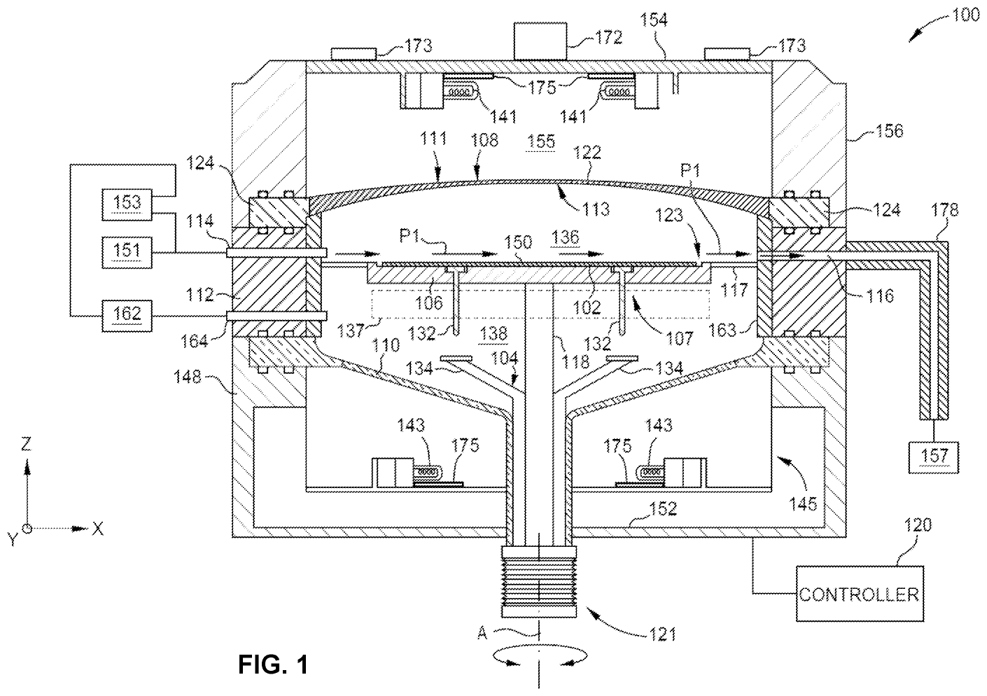

FIG. 1 illustrates a schematic side cross-sectional view of an example semiconductor processing chamber 100, according to some embodiments. The semiconductor processing chamber 100 may represent a deposition chamber. In some embodiments, the semiconductor processing chamber 100 may include or comprise an epitaxial deposition or growth chamber or an etch chamber. The semiconductor processing chamber 100 may be utilized to grow or process an epitaxial film on a substrate 102. The semiconductor processing chamber 100 may create a flow of precursors across a top surface 150 of the substrate 102. Throughout this disclosure, an epitaxial deposition chamber may be used as a specific example of a semiconductor processing chamber. However, the embodiments described herein may be equally applicable to any semiconductor processing chamber. Therefore, any specific reference to an epitaxial deposition chamber may be considered to also refer more generally to any semiconductor processing chamber.

The semiconductor processing chamber 100 may include an upper body 156, a lower body 148 disposed below the upper body 156, and a flow module 112 disposed between the upper body 156 and the lower body 148. The upper body 156, the flow module 112, and the lower body 148 may form a chamber body. Disposed within the chamber body may be a substrate support 106, an upper window 108, a lower window 110 (such as a lower dome), a plurality of upper heat sources 141, and/or a plurality of lower heat sources 143. As shown, a controller 120 may be in communication with the semiconductor processing chamber 100 and may be used to control processes and operations, such as the operations of the methods described herein. The controller 120 and the semiconductor processing chamber 100 may be part of a larger substrate processing system or tool platform.

The semiconductor processing chamber 100 may also include a plurality of upper heat sources 141 that heat a top portion of the semiconductor processing chamber 100, and a plurality of lower heat sources 143 that heat a bottom portion of the semiconductor processing chamber 100. The plurality of upper heat sources 141 may be disposed between the upper window 108 and a lid 154. The plurality of upper heat sources 141 may form a portion of the upper heating module 155. The plurality of lower heat sources 143 may be disposed between the lower window 110 and a chamber floor 152. The plurality of lower heat sources 143 form a portion of a lower heating module 145. In the implementation shown in FIG. 1, the heat sources 141, 143 may be heat lamps. Other heat sources may also be used without restriction, such as resistive heaters, light emitting diodes (LEDs), and/or lasers. The heat sources 141, 143 may be coupled with reflectors 175. The reflectors 175 may be configured to redirect heat energy from the heat sources 141, 143 towards the processing volume 136.

The upper window 108 may be an upper dome and is formed at least partially of an energy transmissive material, such as quartz. Therefore, the upper window 108 may also be referred to as a dome or a quartz dome. The lower window 110 is a lower dome and is formed at least partially of an energy transmissive material, such as quartz. The lower window 110 may also be referred to simply as a dome or quartz dome. The upper window 108 may include a first face 111 that is concave or flat (in the implementation shown in FIG. 1, the first face 111 is concave). The upper window 108 include a second face 113 that is convex. The second face 113 may face the substrate support 106. The upper window 108 may include an inner section 122 and/or an outer section 124. The first face 111 and the second face 113 may form at least part of the inner section 122. The inner section 122 may be transparent, and the outer section 124 may be opaque. The outer section 124 may be received at least partially in one or more sidewalls (such as in the flow module 112) of the semiconductor processing chamber 100.

A process volume 136 and a purge volume 138 may be positioned between the upper window 108 and the lower window 110. The process volume 136 and the purge volume 138 may be part of an internal volume defined at least partially by the upper window 108, the lower window 110, and the one or more liners 163. The upper window 108 may at least partially define the process volume 136.

The internal volume may include the substrate support 106 disposed therein. The substrate support 106 may be disposed between the upper window 108 and the lower window 110. The substrate support 106 may include a support face 123 that supports the substrate 102. The substrate support 106 may also be referred to as a susceptor, platen, or platform. The substrate support 106 may include a top surface on which the substrate 102 is disposed. The substrate support 106 may also be attached to a shaft 118. The shaft 118 may be connected to a motion assembly 121. The motion assembly 121 may include one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 may be sized to accommodate a lift pin 132 for lifting of the substrate 102 from the substrate support 106 either before or after a deposition process is performed. The lift pins 132 may rest on lift pin stops 134 when the substrate support 106 is lowered from a process position to a transfer position. The lift pin stops 134 may be coupled to a second shaft 104. Substrates (such as the substrate 102) may be transferred into and/or out of the internal volume of the semiconductor processing chamber 100 through a transfer door 137 (such as a slit valve). When the transfer door 137 is open, a transfer apparatus (with a substrate supported thereon) may extend into the internal volume through the transfer door 137 such that the lift pins 132 can lift the substrate from the transfer apparatus and land the substrate on the substrate support 106 for processing. After processing, the lift pins 132 may lift the substrate from the substrate support 106 and land the substrate on a transfer apparatus, and the transfer apparatus may be retracted through the open transfer door 137 to remove the substrate from the semiconductor processing chamber 100.

The flow module 112 may include a plurality of gas inlets 114, a plurality of purge gas inlets 164, and one or more gas exhaust outlets 116. The plurality of gas inlets 114 and the plurality of purge gas inlets 164 may be disposed on the opposite side of the flow module 112 from the one or more gas exhaust outlets 116. One or more flow guides 117 may be disposed below the plurality of gas inlets 114 and/or the one or more gas exhaust outlets 116. The one or more flow guides may include, for example, one or more pre-heat rings. The one or more flow guides 117 may be disposed above the purge gas inlets 164. One or more liners 163 may be disposed on an inner surface of the flow module 112 and may protect the flow module 112 from reactive gases used during deposition operations and/or cleaning operations. The gas inlet(s) 114 and the purge gas inlet(s) 164 may each be positioned to flow a gas parallel to the top surface 150 of a substrate 102 disposed within the process volume 136. The gas inlet(s) 114 may be fluidly connected to one or more process gas sources 151 and one or more cleaning gas sources 153. The purge gas inlet(s) 164 may be fluidly connected to one or more purge gas sources 162 and/or the one or more cleaning gas sources 153. The one or more gas exhaust outlets 116 may be fluidly connected to an exhaust pump 157. One or more process gases supplied using the one or more process gas sources 151 may include one or more reactive gases (such as one or more of a silicon (Si), a phosphorus (P), and/or a germanium (Ge) containing gas) and/or one or more carrier gases (such as one or more of nitrogen (N₂) and/or hydrogen (H₂)). One or more purge gases supplied using the one or more purge gas sources 162 may include one or more inert gases (such as one or more of argon (Ar), helium (He), hydrogen (H₂), and/or nitrogen (N₂)). One or more cleaning gases supplied using the one or more cleaning gas sources 153 may include one or more of a hydrogen (H) and/or a chlorine (Cl) containing gas. In some embodiments, the one or more process gases may include silicon phosphide (SiP) and/or phospine (PH₃), and the one or more cleaning gases may include hydrochloric acid (HCl). It will be appreciated that these example gases are non-limiting and that other process, purge, or cleaning gases may be used.

The one or more gas exhaust outlets 116 may be further connected to or include an exhaust system 178. The exhaust system 178 may fluidly connect the one or more gas exhaust outlets 116 and the exhaust pump 157. The exhaust system 178 may assist in the controlled deposition of a layer on the substrate 102. The exhaust system 178 may be disposed on an opposite side of the semiconductor processing chamber 100 relative to the flow module 112.

The controller 120 may include a central processing unit (CPU), a memory containing instructions, and support circuits for the CPU. For example, the controller 120 may include one or more processors. The one or more processors may be distributed between a local controller for the semiconductor processing chamber 100, a tool server on a tool or platform that operates multiple semiconductor processing chambers of different types, and/or at a cloud-based or facility-based server over a network or wireless connection. One or more non-transitory computer-readable media may store instructions that cause the one or more processors of the controller 120 to execute operations described herein. Collectively, the computer-readable media and the one or more processors may make up the controller 120, along with other components, which need not be limited to a single computer system. Instead, the controller 120 may be distributed between number of different computer systems in different locations. In some embodiments, the controller 120 may be communicatively coupled to dedicated controllers, and the controller 120 functions as a central controller. Alternatively, any of the operations performed or described herein may be distributed between the controller 120 and other computing systems. For example, the processing operations, model training, and/or storage of the model may be performed by the controller 120, by another non-premises competing system, by a cloud-based computing system, or by any combination of these or other systems. Some of these processing operations may also be distributed to individual sensors or control circuits in the chamber.

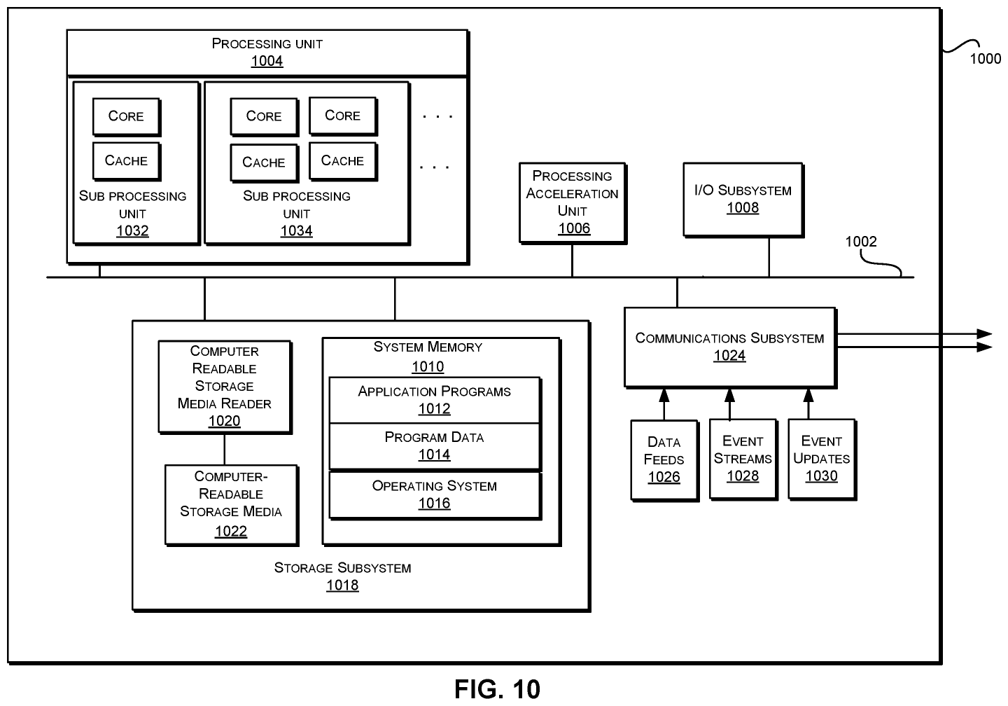

An example of a computer system that may be used to implement the least a portion of the controller 120 is described in detail below in FIG. 10. Operational parameters (a pressure for process gas, a flow rate for process gas, and/or a rotational position of a process kit) and operations may be stored in the computer-readable media as a software routine that is executed or invoked to turn the controller 120 into a specific purpose controller to control the operations of the various chambers/modules described herein. The controller 120 is configured to conduct any of the operations described herein. The various operations described herein may be conducted automatically using the controller 120, or may be conducted automatically or manually with certain operations conducted by a user.

The controller 120 may control various items directly, or via other computers and/or controllers. For example, instructions executed by the controller 120 may cause the semiconductor processing chamber 100 to execute operations in a recipe, such as flowing gases, raising temperatures, receiving a substrate, and so forth. The controller 120 may be configured to control a rotational position, heating, and gas flows through the semiconductor processing chamber 100 by providing an output to controls for the heat sources 141, 143, the gas flow, and the motion assembly 121. The controls may include controls for the upper heat sources 141, the lower heat sources 143, the process gas source 151, the purge gas source 162, the motion assembly 121, and the exhaust pump 157.

The controller 120 may be configured to adjust the output to the controls based off of sensor readings, a system model, and stored readings and calculations. The controller 120 may include embedded software and a compensation algorithm(s) to calibrate measurements. The controller 120 may include one or more machine learning algorithms and/or artificial intelligence algorithms that analyze sensor readings, estimate optimized parameters for deposition operations, etch operations, purge operations, and/or cleaning operations, or evaluate performance or stability within the semiconductor processing chamber 100, such as to determine or estimate when or whether a seasoning process is complete. The one or more machine learning algorithms and/or artificial intelligence algorithms may use, for example, a regression model (such as a linear regression model) or a clustering technique. The algorithm can be unsupervised or supervised.

The lid 154 may include a plurality of sensors disposed therein or thereon, such as for measuring characteristics within the semiconductor processing chamber 100, such as measuring temperatures within the semiconductor processing chamber, monitoring optical conditions within the semiconductor processing chamber 100, or monitoring etch or growth conditions, rates, or characteristics within the semiconductor processing chamber. For example, a central temperature sensor 172 may be disposed on the lid 154 and configured to measure a temperature at or near a center portion of the semiconductor processing chamber 100. More specifically, the central temperature sensor 172 may be configured to measure a temperature of the upper window 108 or quartz dome. The central temperature sensor 172 may also be configured to measure a temperature of the top surface 150 of the substrate 102 and/or the substrate support 106. One or more temperature sensors 173 may also be distributed around a periphery of the semiconductor processing chamber 100. These temperature sensors 173 may be configured to measure specific locations around the periphery of the semiconductor processing chamber 100. For example, these temperature sensors 173 may be pointed towards periphery portions of the upper window 108, towards internal components such as the one or more liners 163, a periphery of the substrate support 106 or susceptor, and so forth. Although not shown explicitly in FIG. 1, the semiconductor processing chamber 100 may include other sensors that are distributed throughout the semiconductor processing chamber 100. For example, a temperature sensor may be disposed in the lower heating module 145 and positioned to measure a temperature at the periphery and/or center of the bottom of the substrate support 106. As another example, one or more optical sensors may be disposed in the lid 154 and positioned to measure optical characteristics of the substrate support 106, upper window 108, lower window 110, or the like. In some examples, one or more piezoelectric or piezoresistive sensors may be positioned within the semiconductor processing chamber 100, such as disposed in or on the substrate support 106 or shaft 118 to characterize a mass change or rate of change during processing. In some examples, upper heat sources 141 and lower heat sources 143 may function or operate as sensors, as power consumption by the upper heat sources 141 and lower heat sources 143 may be a useful characteristic that can provide insights into stability within semiconductor processing chamber 100.

More generally, the plurality of sensors may be directed specifically towards individual components of the semiconductor processing chamber 100. For example, the central temperature sensor 172 may be assigned specifically to measure a temperature at the center of the upper window 108 or the quartz dome. Temperature or optical sensors may be specifically oriented and assigned to measure temperature or optical characteristic underneath the susceptor or substrate support 106 and/or to measure a temperature or optical characteristic of a substrate or a top of the susceptor or substrate support 106. A temperature or optical sensor may be assigned and oriented specifically towards a liner in the semiconductor processing chamber 100. These sensor assignments are provided only by way of example and are not meant to be limiting. Any of the components depicted in FIG. 1 or described above may be assigned a specific sensor that is configured to measure characteristics (e.g., temperature, optical, etc.) of that component. As will be described below, this allows individual sensor data to be used to analyze a characteristic or change in characteristic associated with a specific component or be used for evaluating stability within semiconductor processing chamber 100 on a general or more granular basis. This may also allow the controller to identify a specific component that may cause the semiconductor processing chamber 100 to not perform as desired.

The temperature sensors may be implemented using any type of temperature sensor. For example, some embodiments may use pyrometers. Some embodiments may use thermocouples. Some embodiments may use resistance temperature detectors (RTDs). Some embodiments may use semiconductor-based temperature sensors. Some embodiments may use a temperature scanning system that includes a single sensor (e.g., a pyrometer), and which is configured to scan temperature measurements across the chamber along a predefined path through the upper/lower windows. More generally, the temperature sensors may be implemented with any device configured to provide an output that varies in a manner that is dependent on a temperature in the semiconductor processing chamber 100.

The sensors may be used to sample conditions (e.g., temperature or optical characteristics) inside the semiconductor processing chamber 100 during different operations performed by the semiconductor processing chamber 100. For example, the sensors may be used to acquire measurement data that may be used to train a model.

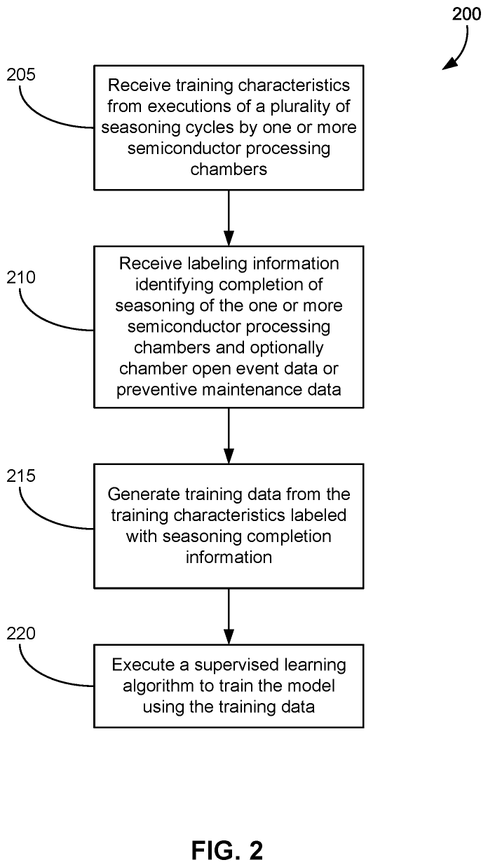

FIG. 2 illustrates a flowchart of a method 200 for training a machine-learning model to characterize seasoning of a semiconductor processing chamber or evaluate completion of a seasoning process, according to some embodiments. This method may be executed by a controller, including any of the controllers and/or computer systems described herein. The semiconductor processing chamber may include an epitaxial deposition chamber, or epi chamber.

The method 200 may include receiving training characteristics from a plurality of executions of a plurality of seasoning cycles executed by one or more semiconductor processing chambers, at block 205. Example training characteristics may comprise time series data obtained from one or more sensors within the semiconductor processing chambers, or virtual sensor data derived from time series data. In some embodiments, a model may be trained for a type of semiconductor processing chamber (e.g., epi chamber), and training characteristics may be received from a plurality of different semiconductor processing chambers of this type (e.g., epi chamber), or from one specific semiconductor processing chamber. Alternatively, some embodiments may train a model for a specific semiconductor processing chamber, and the training characteristics data may be received from multiple executions of the process on the same semiconductor processing chamber. It will be appreciated that temperature data is used as only one example of characteristics that may be used to evaluate stability within a semiconductor processing chamber during seasoning and to determine completion of seasoning. The embodiments and examples described herein may also use any other characteristics of the chamber as a substitute for the temperature. For example, in any embodiment, the temperature measurements may be substituted by and in combination with other parameters, such as optical measurements, heater power, growth rate, etch rate, or the like. Therefore, temperature data is used only as an example and is not meant to be limiting. Any embodiment referring specifically to temperature data may alternatively use any other semiconductor processing chamber characteristic without limitation.

In some cases, the training characteristics may include processed characteristics corresponding to a virtual sensor, such as where one or more sets of sensor data are combined or processed to generate a data set that can function similar to a single set of sensor data. In some cases, sensor data obtained during subsequent seasoning cycles on a single chamber may provide a virtual sensor data that may establish a change in characteristics between the subsequent seasoning cycles. As one example, where time series of temperature sensor measurements are obtained for different seasoning cycles, an analysis can be performed on the time series to establish a variance or other metric of how different the time series of one seasoning cycle is from the seasoning cycle immediately before it. In some cases, as seasoning advances towards completion, the time series of temperature or other sensor data may change smaller amounts between seasoning cycles, so determining a variation in the time series data may provide a useful virtual sensor signal that can be used to evaluate seasoning progress.

Method 200 may also include receiving labeling information identifying completion of the seasoning of the one or more semiconductor processing chambers during the plurality of seasoning cycles, at block 210. Labeling information may be received in some cases as user input, and establish when an expert or other user determines, based on the training characteristics, when seasoning was completed. That is, the label may identify a particular seasoning cycle at which seasoning is complete or a number of seasoning cycles after which seasoning is completed. In some cases, labeling information can specify a threshold value for a virtual sensor measurement, such as a variance, below which seasoning is automatically considered complete, such as when one or multiple virtual sensor measurements in a row fall below the threshold value. In some examples, additional labeling information may be provided in addition to an indicator of a particular seasoning cycle at which seasoning is complete or a number of seasoning cycles after which seasoning is completed. For example, labeling information may also include chamber open event data or preventive maintenance event data, establishing information about the conditions to which the semiconductor processing chambers were subjected to prior to the seasoning process. For example, information about environmental conditions (e.g., humidity, temperature) or duration during the chamber open event may be used to label the training characteristics. Similarly, information about the particular preventive maintenance performed on the semiconductor processing chamber (e.g., indication of a change in a particular part or cleaning process) may be used to label the training characteristics.

Method 200 may also include generating training data from the training characteristics labeled with seasoning completion information, chamber open event data, and/or preventive maintenance data, at block 215, and executing a supervised learning algorithm to train the model using the training data, at block 220. In some cases, the labeling information can be used by the model to develop formulae characterizing how the training characteristics change as a function of seasoning cycle so that a prediction of when seasoning is complete can be evaluated based on a small number of seasoning cycles and optionally the chamber open event data and/or preventive maintenance data.

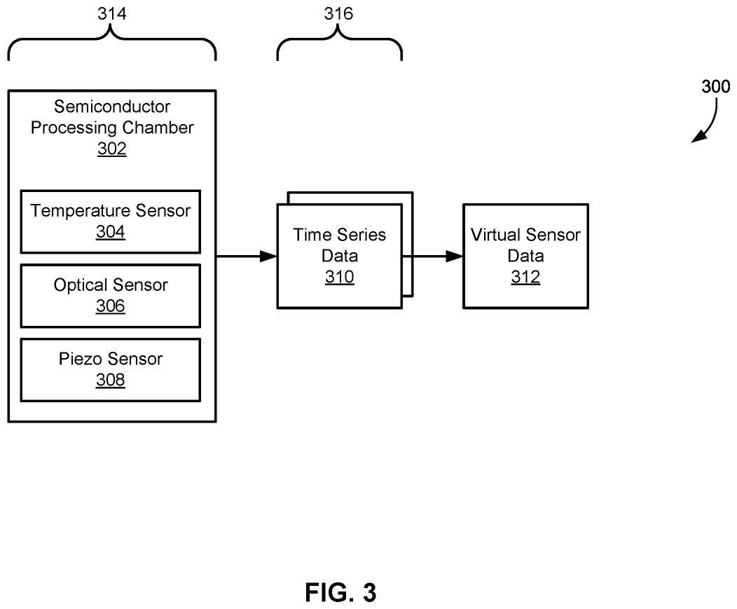

FIG. 3 illustrates a block diagram of how virtual sensor data 312, such as exemplified as variance value data, may be generated from the characteristics measured during seasoning, according to some embodiments. A semiconductor processing chamber 302 may include a plurality of temperature sensors 304, a plurality of optical sensors 306, and/or a plurality of piezo sensors 308, such as those illustrated in or described above with reference to in FIG. 1. When a seasoning cycle is executed by the semiconductor processing chamber 302, the temperature sensors 304, the optical sensors 306, and/or the piezo sensors 308 may record sensor data measurements in real time throughout the process. A sensor sampling stage 314 may generate time series data 310 as a series of successive measurements from the temperature sensors 304, optical sensors 306, and/or the piezo sensors 308. The time series data 310 may then be processed by a conversion stage 316 that converts the time series data 310 to virtual sensor data 312.

For example, the seasoning process executed by the semiconductor processing chamber 302 may include a plurality of seasoning cycles. Each cycle may be associated with a particular set of processing conditions, such as an epitaxial growth condition or an etch condition. In some cases, a single cycle may comprise two sub-cycles (e.g., a growth condition sub-cycle and an etch-condition sub-cycle). During a single cycle or sub-cycle, the characteristics of the semiconductor processing chamber 302 may be monitored by the temperature sensors 304, the optical sensors 306, and/or the piezo sensors 308. For example, a particular processing condition may include heating the semiconductor processing chamber to a particular temperature set point, but the temperature may vary over time, such as while the temperature is reaching equilibrium. In some cases, chemical reactions may take place during etch or epitaxial growth, which can impact the temperature or rate at which the temperature reaches equilibrium. In some examples, generating the virtual sensor data may compare time series data for one cycle or sub-cycle with time series data for another cycle or sub-cycle (e.g., a cycle or sub-cycle immediately before), such as to derive a variation (e.g., variance) in the time series data between cycles or sub-cycles.

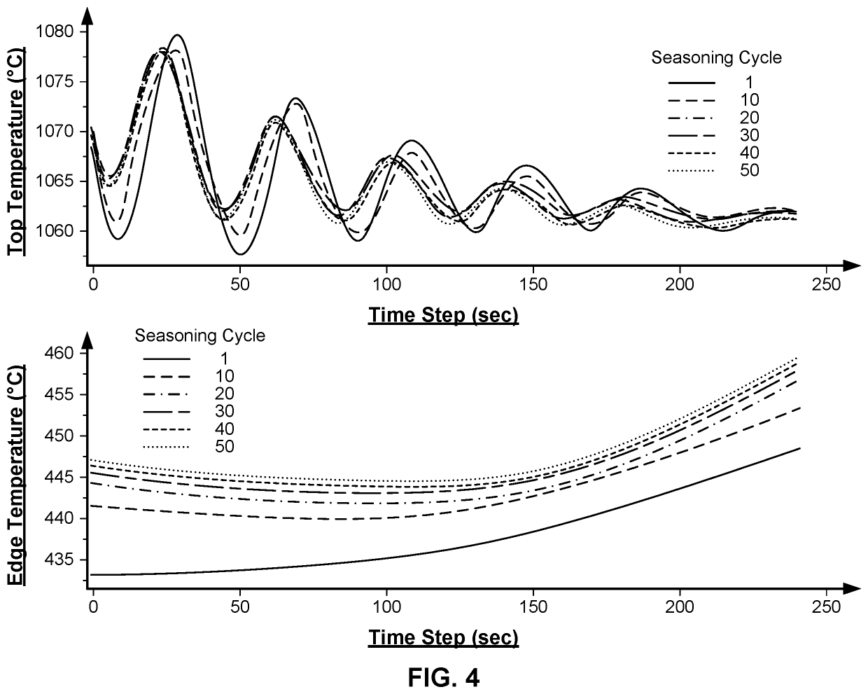

FIG. 4 provides examples of time series data of temperature measurements at two different positions within a semiconductor processing chamber during several seasoning cycles, according to some embodiments. Although data for only the first and every tenth cycle is shown in FIG. 4 through the fiftieth seasoning cycle, this limited amount of data is only shown to provide clarity and not obscure other details. In practice, time series data of this nature for each seasoning cycle may be obtained.

The time series data 310, of which FIG. 4 provides some examples, may be combined at the conversion stage 316 to generate virtual sensor data 312. As noted above, an example of virtual sensor data that may be useful for evaluating progression of seasoning of a semiconductor processing chamber may be a comparative evaluation of the sensor data for a particular seasoning cycle with the sensor data for an immediately previous seasoning cycle. For example, the temperature time series data for seasoning cycle 2 (not shown in FIG. 4) may be directly compared with the temperature time series data for seasoning cycle 1. In some examples a difference or ratio of the temperature time series data can be computed, which can result in a time series of difference or ratio data, which may be used as virtual sensor data 312. In some cases, the time series of difference or ratio data may be consolidated to a single value, such as sum or average of the difference or ratio data, which may provide a single value characterizing a seasoning cycle and how the time series data for a particular characteristic changes between seasoning cycles. In other examples, a variance (e.g., the average squared deviation from a mean) may be determined. In some examples, this single value may be used as virtual sensor data 312. In some cases, multiple different comparisons of time series data from different sensors can be obtained in this way and further combined, such as according to various weighting factors to generate virtual sensor data 312. It will be appreciated that these are merely a few examples of how virtual sensor data 312 may be generated and are not intended to be limiting.

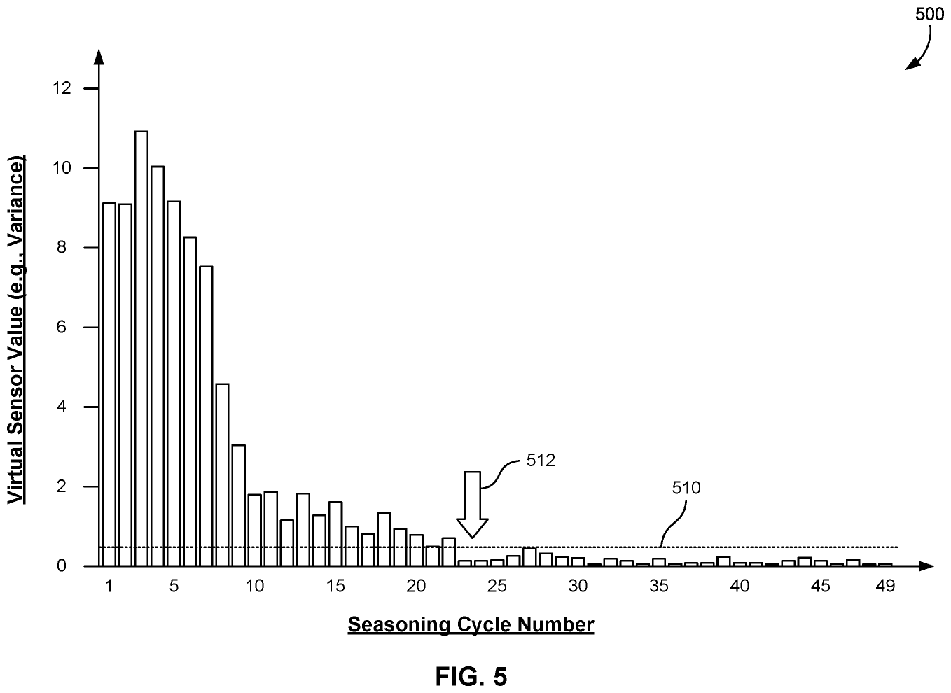

FIG. 5 provides an example bar graph 500 showing virtual sensor data information as a function of seasoning cycle, here provided as a variance value between subsequent cycles for the first 50 cycles. FIG. 5 also shows a threshold value 510, which may indicate the variance value below which seasoning may be considered to be completed. FIG. 5 also shows a label 512 indicating that seasoning is complete at around seasoning cycle 23 or 24.

In cases where virtual sensor data as shown in FIG. 5 is used as training data, a user may provide input corresponding to label 512 establishing when seasoning is considered complete, such as at seasoning cycle 23 or 24. For example, a position of label 512 may be input by a user. Additionally or alternatively, a user may provide input corresponding to threshold 510 as labeling information, establishing the virtual sensor value where seasoning is determined to be complete, such as once one or multiple (e.g., 2, 3, 4, 5, 6, etc.) virtual sensor values fall below the threshold 510.

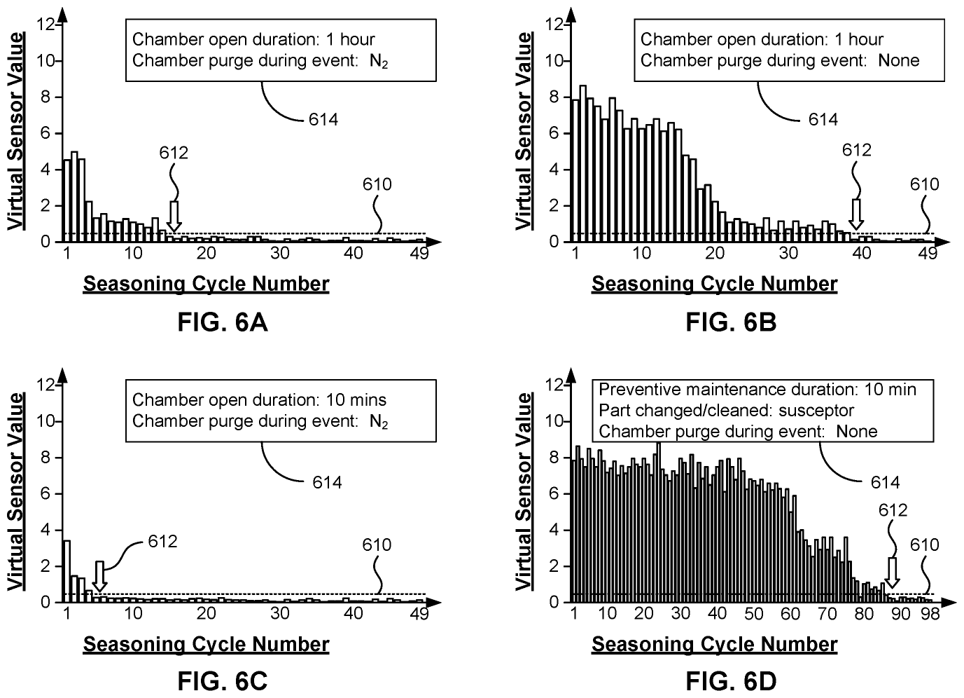

FIG. 6A, FIG. 6B, FIG. 6C, and FIG. 6D provide additional example bar graphs showing virtual sensor data information as a function of seasoning cycle for different seasoning operations. FIG. 6A, FIG. 6B, FIG. 6C, and FIG. 6D also provide threshold 610 and labeling information 612. Here, additional labeling information 614 also includes information relating to a chamber open event or preventive maintenance event.

In some cases, sensor data or virtual sensor data, similar to that shown in FIG. 4, FIG. 5, or FIGS. 6A-6D, may be obtained during a seasoning process and displayed on an interface (e.g., display) during seasoning in real time as the data is collected or processed, such as to allow a user to monitor progress of seasoning. Optionally, an interface may be used for obtaining the labeling information as an input, such as during a training process, allowing positioning of an indicator, receiving a selection from a drop-down menu, or receiving a text input.

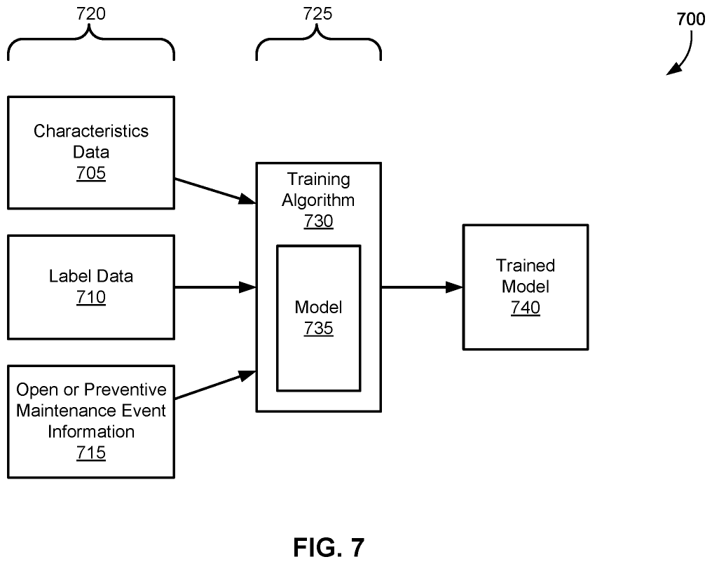

Turning back to the training method of flowchart 200 in FIG. 2, the method may also include generating training data from the training characteristics labeled with seasoning completion information. FIG. 7 illustrates a flow diagram 700 for training a model to predict seasoning completion, according to some embodiments and examples. The training characteristics data 705 may be labeled using corresponding label data 710 for each semiconductor processing chamber. For example, the semiconductor processing chamber may perform the seasoning process and collect characteristics data 705 using one or more sensors, and label data 710 may be determined, such as via user input. Here, the label data 710 may correspond to or indicate a seasoning cycle number where seasoning was determined to be complete, such as according to user or expert determination. In some cases, the label data 710 indicating the seasoning cycle number where seasoning was determined to be complete may be automatically determined, such as based on one or more characteristics data 705 meeting or reaching a threshold value. In some examples, a number of seasoning cycles for which threshold values need to be met before seasoning is determined to be automatically completed may be adjustable or provided as labeling information. In some examples, a threshold value may be adjustable or provided as labeling information.

Additionally, chamber open or preventive maintenance event information 715 may be determined, such as via user input or derived from one or more data storage systems, and optionally used as additional labeling information for generating training data or training a machine-learning model. As described above, chamber open or preventive maintenance event information 715 can be useful for associating with a number of seasoning cycles until seasoning completion, as various physical processes associated with a chamber open or preventive maintenance event can impact the number of cycles until seasoning completes. Having this chamber open or preventive maintenance event available as labeling information can be useful for improving the training of a model.

The characteristics data 705, labeled with one or both of the label data 710 and/or the chamber open or preventive maintenance event information 715 may be considered a training set 720 for training the model. Although only a single training set 720 is illustrated in FIG. 7, it should be understood that multiple training sets may be provided to the training algorithm for the model from multiple chambers or from multiple processes from the same chamber.

In the training method of flowchart 200 in FIG. 2, the method may also include executing a supervised learning algorithm to train the model using the training data. FIG. 7 illustrates how a training stage 725 may include performing a training algorithm 730 on a model 735. The model 735 may include a machine-learning model that is trained to model seasoning of a semiconductor processing chamber (e.g., an epitaxial chamber), such as after a chamber open event or preventive maintenance event. The model 735 may account for the stability of surfaces within the semiconductor processing chamber, and thus the training algorithm 730 may receive the characteristics data from component-specific sensors throughout the semiconductor chamber. For example, when the training algorithm 730 adjusts the weights or parameters of the model 735, these weights or parameters may be trained such that the model 735 approximates the passivation behavior of various components of the semiconductor processing chamber during epitaxial growth conditions or etch conditions. The training stage 725 may also be trained as a classification model that uses characteristics data and the chamber open or preventive maintenance event information in order to outputs a classification based on how well the input data matches the training data. For example, the model 735 may be implemented using a neural network or a convolution learn network to classify the inputs, although the model is not meant to be limited to neural networks. Any type of machine-learning model may be used, including data-mode models, physics models, hybrid models, and so forth.

After the training stage 725 is complete, this process may generate a trained model 740. The trained model 740 may now be used to predict whether seasoning of a semiconductor processing chamber is complete or other information about seasoning completion immediately upon completion of each seasoning cycle or sub-cycle. Additionally, the trained model 740 may be continuously retrained and/or refined over time as new training data becomes available. For example, some implementations may collect characteristics data regularly from existing semiconductor processing chambers during seasoning and request or obtain confirmation from users whether cycling is complete for purposes of labeling. This information may be combined to form new labeled training data, and the training stage 725 may be repeated to refine the trained model 740 on an ongoing basis or as needed.

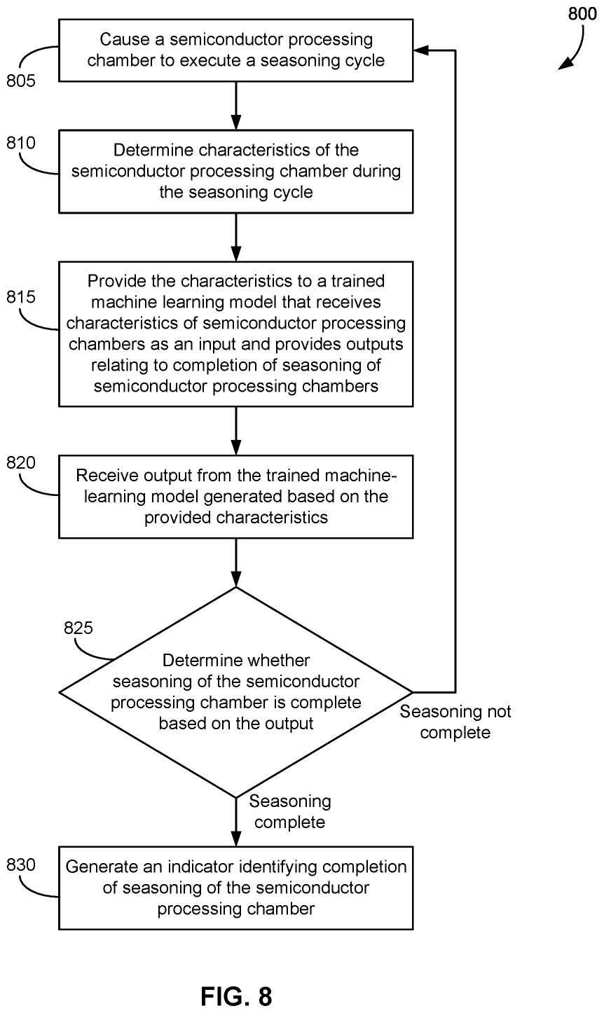

FIG. 8 illustrates a flowchart of a method 800 for seasoning semiconductor processing chambers, according to some examples. This method may be executed using the trained model 740 as described above. For example, a number of different scenarios may benefit from the use of the trained model 740 to characterize seasoning of a semiconductor processing chamber and predict whether the seasoning process is complete and/or when the seasoning process will be completed. For example, when a new semiconductor processing chamber is added to a manufacturing facility, the ability of the new semiconductor processing chamber to have a stable condition with controllable processing (e.g., etching or epitaxial growth) may be of concern. The trained model 740 may be used to determine how long it may take for the seasoning of the new semiconductor processing chamber to be complete so that it can be used in production. Similarly, as existing semiconductor processing chambers are used and opened or have preventive maintenance performed on them, the trained model 740 may be used to determine how long it may take for the seasoning of the semiconductor processing chamber to be complete so that it can be again used in production. For example, during one or more seasoning cycles, characteristics data can be obtained and provided to the trained model 735 as an input. The output of the trained model 735 may then indicate whether seasoning is completed, how many seasoning cycles are anticipated until seasoning is completed, and/or a duration of time until seasoning is completed.

The method may include executing a seasoning cycle or sub-cycle using a semiconductor processing chamber or causing a semiconductor processing chamber to execute a seasoning cycle or sub-cycle (805), such as a process that varies or causes a temperature, pressure, gas component mixture in the chamber to vary during the process, such as to establish etch conditions or epitaxial growth conditions, for example. This process may be the same process described above in FIGS. 3-5 and used to generate various characteristics data. For example, the process may include sequentially establishing etch conditions and growth conditions within the semiconductor processing chamber, which may passivate surfaces therein and may optionally result in removal of undesirable impurities from within the semiconductor processing chamber. The seasoning cycle may take place without a semiconductor substrate (e.g., a wafer) present within the semiconductor processing chamber, and can result in repeatedly growing and/or etching material on surfaces of other components of the semiconductor processing chamber and building up passivation layers that can serve to provide stable conditions within the semiconductor processing chamber during etch or growth conditions.

The method may also include determining characteristics of the semiconductor processing chamber during the seasoning cycle, such as temperature measurements, optical measurements, piezo measurements (810). As described above, temperature, optical, or piezo sensors may be associated with individual components and/or locations in the semiconductor processing chamber. These sensors may record various physical parameters during the seasoning cycle or sub-cycle as a set of time series data. The method may optionally include deriving virtual sensor data from the measured characteristics. As described above, the virtual sensor data may be derived by comparing time series data for a given seasoning cycle with time series data from an immediately prior seasoning cycle, such as to provide measure of the variability of various characteristics from seasoning cycle to seasoning cycle.

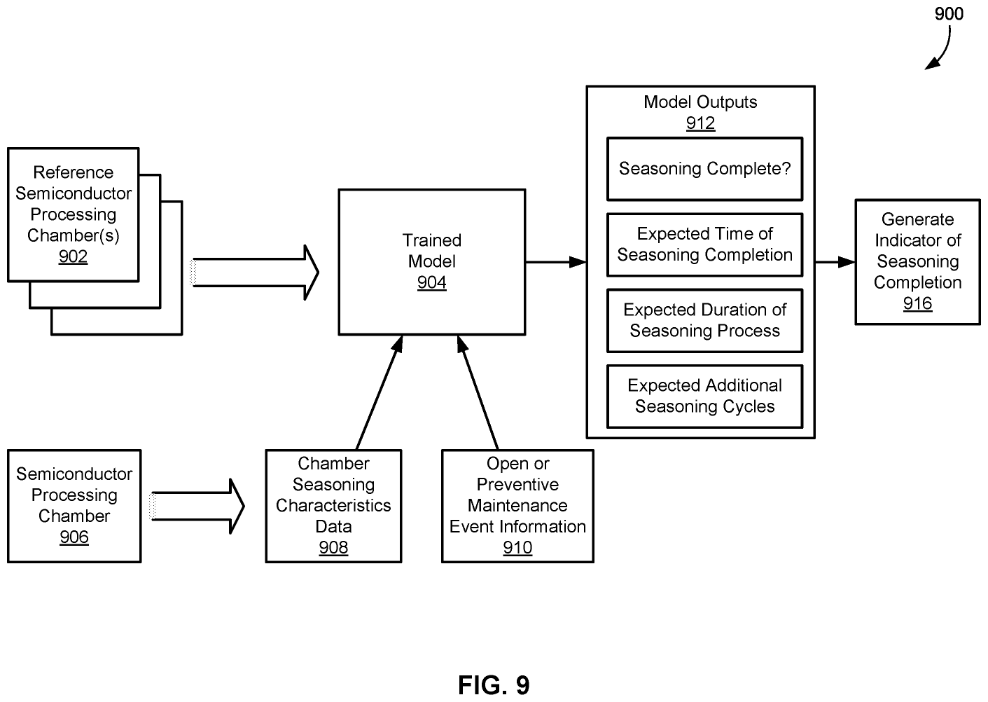

The method may additionally include providing the characteristics data to a trained model (815). As described above, the trained model may be configured to receive the characteristics data as an input and provide an output or outputs relating to completion of seasoning. The output may indicate whether the seasoning process is complete, or may provide information as to expected completion of the seasoning process. FIG. 9 illustrates a flow diagram 900 of using a trained model 904 to predict the completion of seasoning of a semiconductor processing chamber, according to some embodiments. As described in detail above, a plurality of labeled training data may be provided from one or more reference semiconductor processing chambers 902 in order to train or retrain the trained model 904. When a semiconductor processing chamber 906 is subjected to a chamber open event or preventive maintenance event, the process described above may be executed for the semiconductor processing chamber 906 to perform seasoning and determine when seasoning is completed without having to undergo excessive seasoning cycles beyond those needed to ensure adequate seasoning. During various seasoning cycles, characteristics data 908 may be obtained and provided as an input to the trained model 904.

Some embodiments may also provide chamber open event or preventive maintenance event information 910 to the trained model 904 as a secondary input. This information may be provided as a supplement and used by the trained model 904 to more accurately determine seasoning completion or estimate the amount of time or number of seasoning cycles needed until seasoning completion is achieved. For example, the open event or preventive maintenance event information 910 can increase the accuracy of the trained model 904 since this additional information can provide a more complex understanding of the amount of seasoning cycles that may be required to suitably passivate surfaces and/or remove impurities that may have been introduced during the chamber open or preventive maintenance event.

Turning back to FIG. 8, method 800 may also include receiving the output from the trained model providing seasoning completion information generated based on the provided characteristics (820). With reference to FIG. 9, the output 912 of the trained model 904 may include binary (e.g., 0/1 or true/false) and/or scalar values that express whether seasoning is completed, a variance level, a deviation from a threshold value signifying completion, a number of additional seasoning cycles expected until seasoning is complete, a time duration expected until seasoning is complete, or an expected time of seasoning completion.

The method 800 may further include determining whether seasoning of the semiconductor processing chamber is complete based on the output (825). In some examples, the output may directly signify whether seasoning is completed, such as in the form of a binary value (yes/no). In other examples, the output may indicate the number of additional seasoning cycles anticipated until seasoning is completed, such as in the form of an integer value; if seasoning is complete, the integer value may be zero, and if seasoning is not complete, the integer value may be one or more than one.

In the even that seasoning is not determined to be completed, method 800 may return to operation 805, where the semiconductor processing chamber may execute an additional seasoning cycle, followed by measuring characteristics during the additional seasoning cycle (810), providing the additional characteristics to the trained machine-learning model (815), and receiving output from the trained machine-learning model based on the additional characteristics (820), and then again evaluating whether seasoning is complete (825). Once seasoning is determined to be complete, method 800 can then progress to generating an indicator identifying completion of seasoning (830).

Again, with reference to FIG. 9, an indicator of or relating to seasoning completion may be generated, optionally at any time during a seasoning process. The indicator may provide a notification whether seasoning is complete or not, an expected time or expected number of additional seasoning cycles until seasoning is complete, an expected duration or timer countdown of the seasoning process, which can optionally update in real time as additional characteristics data is obtained and modeling of seasoning is evaluated. Optionally, the indicator can provide characteristics data, such as in the form of time series data, which can provide such information to an expert or other user, such as for troubleshooting or other informational purposes. In some examples, the indicator can provide virtual sensor data, such as variance data, showing progress of seasoning in a form that may be more easily understood by the expert or other user.

It should be appreciated that the specific steps illustrated in FIG. 2 and FIG. 8 provide particular methods of training and using a model to predict semiconductor processing chamber seasoning performance, according to various embodiments. Other sequences of steps may also be performed according to alternative embodiments. For example, alternative embodiments may perform the steps outlined above in a different order. Moreover, the individual steps illustrated in FIG. 2 and FIG. 8 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

FIG. 10 illustrates an exemplary computer system 1000, in which various embodiments may be implemented. The system 1000 may be used to implement any of the computer systems described above. As shown in the figure, computer system 1000 includes a processing unit 1004 that communicates with a number of peripheral subsystems via a bus subsystem 1002. These peripheral subsystems may include a processing acceleration unit 1006, an I/O subsystem 1008, a storage subsystem 1018 and a communications subsystem 1024. Storage subsystem 1018 includes tangible computer-readable storage media 1022 and a system memory 1010.

Bus subsystem 1002 provides a mechanism for letting the various components and subsystems of computer system 1000 communicate with each other as intended. Although bus subsystem 1002 is shown schematically as a single bus, alternative embodiments of the bus subsystem may utilize multiple buses. Bus subsystem 1002 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1004, which can be implemented as one or more integrated circuits (e.g., a conventional microprocessor or microcontroller), controls the operation of computer system 1000. One or more processors may be included in processing unit 1004. These processors may include single core or multicore processors. In certain embodiments, processing unit 1004 may be implemented as one or more independent or sub processing units 1032 and/or 1034 with single or multicore processors included in each processing unit. In other embodiments, processing unit 1004 may also be implemented as a quad-core processing unit formed by integrating two dual-core processors into a single chip.

In various embodiments, processing unit 1004 can execute a variety of programs in response to program code and can maintain multiple concurrently executing programs or processes. At any given time, some or all of the program code to be executed can be resident in processor(s) 1004 and/or in storage subsystem 1018. Through suitable programming, processor(s) 1004 can provide various functionalities described above. Computer system 1000 may additionally include a processing acceleration unit 1006, which can include a digital signal processor (DSP), a special-purpose processor, and/or the like.

I/O subsystem 1008 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. Additionally, user interface input devices may include voice recognition sensing devices that enable users to interact with voice recognition systems, through voice commands. User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments, augmented reality (AR) input/output devices, virtual reality (VR) input/output devices, and/or the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1000 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1000 may comprise a storage subsystem 1018 that comprises software elements, shown as being currently located within a system memory 1010. System memory 1010 may store program instructions that are loadable and executable on processing unit 1004, as well as data generated during the execution of these programs.

Depending on the configuration and type of computer system 1000, system memory 1010 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1004. In some implementations, system memory 1010 may include multiple different types of memory, such as static random access memory (SRAM) or dynamic random access memory (DRAM). In some implementations, a basic input/output system (BIOS), containing the basic routines that help to transfer information between elements within computer system 1000, such as during start-up, may typically be stored in the ROM. By way of example, and not limitation, system memory 1010 also illustrates application programs 1012, which may include client applications, Web browsers, mid-tier applications, relational database management systems (RDBMS), etc., program data 1014, and an operating system 1016. By way of example, operating system 1016 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1018 may also provide a tangible computer-readable storage medium for storing the basic programming and data constructs that provide the functionality of some embodiments. Software (programs, code modules, instructions) that when executed by a processor provide the functionality described above may be stored in storage subsystem 1018. These software modules or instructions may be executed by processing unit 1004. Storage subsystem 1018 may also provide a repository for storing data used in accordance with some embodiments.

Storage subsystem 1018 may also include a computer-readable storage media reader 1020 that can further be connected to computer-readable storage media 1022. Together and, optionally, in combination with system memory 1010, computer-readable storage media 1022 may comprehensively represent remote, local, fixed, and/or removable storage devices plus storage media for temporarily and/or more permanently containing, storing, transmitting, and retrieving computer-readable information.

Computer-readable storage media 1022 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1000.

By way of example, computer-readable storage media 1022 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1022 may include, but is not limited to, Zip® drives, flash memory cards, universal serial bus (USB) flash drives, secure digital (SD) cards, DVD disks, digital video tape, and the like. Computer-readable storage media 1022 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1000.

Communications subsystem 1024 provides an interface to other computer systems and networks. Communications subsystem 1024 serves as an interface for receiving data from and transmitting data to other systems from computer system 1000. For example, communications subsystem 1024 may enable computer system 1000 to connect to one or more devices via the Internet. In some embodiments communications subsystem 1024 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1024 can provide wired network connectivity (e.g., Ethernet) in addition to or instead of a wireless interface.

In some embodiments, communications subsystem 1024 may also receive input communication in the form of structured and/or unstructured data feeds 1026, event streams 1028, event updates 1030, and the like on behalf of one or more users who may use computer system 1000.

By way of example, communications subsystem 1024 may be configured to receive data feeds 1026 in real-time from users of social networks and/or other communication services or web feeds such as Rich Site Summary (RSS) feeds, and/or real-time updates from one or more third party information sources.

Additionally, communications subsystem 1024 may also be configured to receive data in the form of continuous data streams, which may include event streams 1028 of real-time events and/or event updates 1030, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1024 may also be configured to output the structured and/or unstructured data feeds 1026, event streams 1028, event updates 1030, and the like to one or more databases that may be in communication with one or more streaming data source computers coupled to computer system 1000.

Computer system 1000 can be one of various types, including a handheld portable device (e.g., an iPhone® cellular phone, an iPad® computing tablet, a PDA), a wearable device, a PC, a workstation, a mainframe, a kiosk, a server rack, or any other data processing system.

Due to the ever-changing nature of computers and networks, the description of computer system 1000 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of seasoning a semiconductor processing chamber, the method comprising:
executing a seasoning cycle using a semiconductor processing chamber;
determining characteristics of the semiconductor processing chamber during the seasoning cycle;
providing the characteristics to a trained machine-learning model that is configured to receive characteristics of semiconductor processing chambers as an input and provide outputs relating to completion of seasoning of the semiconductor processing chambers;
receiving output from the trained machine-learning model generated based on the characteristics;
determining that seasoning of the semiconductor processing chamber is not complete based on the output;
executing an additional seasoning cycle using the semiconductor processing chamber;
determining additional characteristics of the semiconductor processing chamber during the additional seasoning cycle;
providing the characteristics of the semiconductor processing chamber during the additional seasoning cycle to the trained machine-learning model;
receiving additional output from the trained machine-learning model;
determining that seasoning of the semiconductor processing chamber is complete based on the additional output; and
generating an indicator identifying completion of seasoning of the semiconductor processing chamber.

2. The method of claim 1, wherein the output indicates completion of seasoning of the semiconductor processing chamber, an expected time of completion of seasoning of the semiconductor processing chamber, an expected duration of seasoning of the semiconductor processing chamber, or an expected number of additional seasoning cycles for completion of seasoning of the semiconductor processing chamber, and wherein method further comprises generating an indicator identifying one or more of an expected time of completion of seasoning of the semiconductor processing chamber, an expected duration of seasoning of the semiconductor processing chamber, or an expected number of additional seasoning cycles for completion of seasoning of the semiconductor processing chamber.

3. The method of claim 1, further comprising subsequent to determining that seasoning of the semiconductor processing chamber is not complete based on the output:
generating an indicator identifying an expected time of completion of seasoning of the semiconductor processing chamber, an expected duration of seasoning of the semiconductor processing chamber, or an expected number of additional seasoning cycles for completion of seasoning of the semiconductor processing chamber.

4. The method of claim 1, wherein execution of a seasoning cycle comprises:
controlling the semiconductor processing chamber to establish an etch condition within the semiconductor processing chamber; and
controlling the semiconductor processing chamber to establish an epitaxial growth condition within the semiconductor processing chamber.

5. The method of claim 1, wherein the characteristics comprise one or more of a temperature within the semiconductor processing chamber during the seasoning cycle, a thickness of an epitaxial layer generated within the semiconductor processing chamber, a power delivered to a heater associated with the semiconductor processing chamber, a power setting for a heater associated with the semiconductor processing chamber, a growth rate within the semiconductor processing chamber during the seasoning cycle, an etch rate within the semiconductor processing chamber during the seasoning cycle, an optical condition within the semiconductor processing chamber during the seasoning cycle, a pressure within the semiconductor processing chamber during the seasoning cycle, a gas composition within the semiconductor processing chamber during the seasoning cycle, a flow rate into or out of the semiconductor processing chamber during the seasoning cycle, a change in any of these, a physical or structural parameter associated with the semiconductor processing chamber, or any combination of these.

6. The method of claim 1, further comprising, before providing the characteristics to the machine-learning model, training the machine-learning model, wherein training the machine-learning model comprises:
receiving training characteristics from a plurality of executions of seasoning cycles executed by one or more semiconductor processing chambers;
generating training data based on the training characteristics, wherein the training data is generated using labeling information identifying completion of seasoning of the one or more semiconductor processing chambers; and
executing a supervised learning algorithm to train the machine-learning model using the training data.

7. The method of claim 6, wherein:
the one or more semiconductor processing chambers and the semiconductor processing chamber are a same chamber; and
determining that seasoning of the semiconductor processing chamber is complete comprises comparing characteristics of the semiconductor processing chamber with previously determined characteristics of the semiconductor processing chamber.

8. The method of claim 1, wherein the machine learning model compares characteristics for a seasoning cycle with corresponding characteristics for an immediately previous seasoning cycle to evaluate completion of seasoning of the semiconductor processing chamber.

9. A system comprising:
one or more processors; and
one or more non-transitory computer readable storage devices comprising instructions that, when executed by the one or more processors, cause the one or more processors to perform operations comprising:
causing the semiconductor processing chamber to execute a seasoning cycle;
determining characteristics of the semiconductor processing chamber during the seasoning cycle;
providing the characteristics to a trained machine-learning model that is configured to receive characteristics of semiconductor processing chambers as an input and provide outputs relating to completion of seasoning of the semiconductor processing chambers;
receiving the output from the trained machine-learning model;
determining that seasoning of the semiconductor processing chamber is not complete based on the output;
causing the semiconductor processing chamber to execute an additional seasoning cycle;
continuing determining characteristics of the semiconductor processing chamber during the additional seasoning cycle;
providing the characteristics of the semiconductor processing chamber during the additional seasoning cycle to the trained machine-learning model;
receiving additional output from the trained machine-learning model;
determining that seasoning of the semiconductor processing chamber is complete based on the additional output; and
generating an indicator identifying completion of seasoning of the semiconductor processing chamber.

10. The system of claim 9, further comprising one or more sensors in data communication with the one or more processors for determining characteristics of the semiconductor processing chamber during seasoning cycles.

11. The system of claim 10, wherein:
the characteristics comprise a time series of data obtained from the one or more sensors; or
the characteristics comprise a comparison using a first time series of data obtained from the one or more sensors during a first seasoning cycle and a second time series of data obtained from the one or more sensors during a second seasoning cycle immediately previous to the first seasoning cycle.

12. The system of claim 9, wherein the seasoning cycle comprises:
controlling the semiconductor processing chamber to establish an etch condition within the semiconductor processing chamber; and
controlling the semiconductor processing chamber to establish an epitaxial growth condition within the semiconductor processing chamber.

13. The system of claim 9, wherein the semiconductor processing chamber comprises one or more of a quartz dome, a flow module, or a susceptor.

14. The system of claim 13, further comprising one or more sensors positioned to measure characteristics of a surface of one or more of the quartz dome, the flow module, the susceptor, or a substrate within the semiconductor processing chamber.

15. A non-transitory computer-readable medium comprising instructions that, when executed by one or more processors, cause the one or more processors to perform operations comprising:
causing a semiconductor processing chamber to execute a seasoning cycle;
determining characteristics of the semiconductor processing chamber during the seasoning cycle;
providing the characteristics to a trained machine-learning model that is configured to receive characteristics of semiconductor processing chambers as an input and provide outputs relating to completion of seasoning of the semiconductor processing chambers;
receiving the output from the trained machine-learning model;
determining that seasoning of the semiconductor processing chamber is not complete based on the output;
causing the semiconductor processing chamber to execute an additional seasoning cycle;
continuing determining characteristics of the semiconductor processing chamber during the additional seasoning cycle;
providing the characteristics of the semiconductor processing chamber during the additional seasoning cycle to the trained machine-learning model;
receiving additional output from the trained machine-learning model;
determining that seasoning of the semiconductor processing chamber is complete based on the additional output; and
generating an indicator identifying completion of seasoning of the semiconductor processing chamber.

16. The non-transitory computer-readable medium of claim 15, wherein the trained machine-learning model is trained to model seasoning of the semiconductor processing chamber following a chamber open event or a preventive maintenance event associated with the semiconductor processing chamber.

17. The non-transitory computer-readable medium of claim 16, wherein the operations further include obtaining user inputs corresponding to one or more of identification of a duration of the chamber open event or the preventive maintenance event, a change in components of the semiconductor processing chamber during the chamber open event or the preventive maintenance event, environmental conditions during the chamber open event or the preventive maintenance event, maintenance procedures or protocols applied to the semiconductor processing chamber during the chamber open event or the preventive maintenance event, or a severity rating for the chamber open event or the preventive maintenance event, wherein the trained machine-learning model is further configured to use the user inputs when generating the outputs relating to completion of seasoning of the semiconductor processing chambers.

18. The non-transitory computer-readable medium of claim 15, wherein output from the trained machine-learning model comprises an indication of completion or non-completion of seasoning of the semiconductor processing chamber and one or more variance values determined by comparing the characteristics of the semiconductor processing chamber during a first seasoning cycle with characteristics of the semiconductor processing chamber during a second seasoning cycle immediately previous to the first seasoning cycle.

19. The non-transitory computer-readable medium of claim 15, wherein determining that seasoning of the semiconductor processing chamber is complete based on the additional output comprises:
deriving a variance value between the output and the additional output; and
determining that the variance value is less than a target variance value.

20. The non-transitory computer-readable medium of claim of claim 19, wherein the operations further comprise receiving input corresponding to a tolerance to the trained machine-learning model that indicates an allowed deviation from the target variance value.
